(19) United States
(12) Patent Application Publication
(10) Pub. No.: US 2017/0044661 A1
(43) Pub. Date: Feb. 16, 2017

(54) DYNAMIC APERTURE FOR THREE-DIMENSIONAL CONTROL OF THIN-FILM DEPOSITION AND ION-BEAM EROSION

(71) Applicant: UChicago Argonne, LLC, Chicago, IL (US)

(72) Inventors: Raymond P. Conley, Mokena, IL (US); David Windt, New York, NY (US)

(73) Assignee: UChicago Argonne, LLC, Chicago, IL (US)

(21) Appl. No.: 15/234,792

(22) Filed: Aug. 11, 2016

Related U.S. Application Data
(60) Provisional application No. 62/204,377, filed on Aug. 12, 2015.

(51) Int. Cl. C23C 14/54; H01J 37/34; H01J 37/30; C23C 14/35; H01J 37/305

(52) U.S. Cl. CPC C23C 14/542; C23C 14/35; H01J 37/3053; H01J 37/3002; H01J 37/347; H01J 2237/3151; H01J 2237/3174

(57) ABSTRACT

A dynamic aperture system includes at least one baffle array including a plurality of baffle elements, at least one source configured to provide atoms for differential deposition or ions for differential erosion, and an actuator configured to independently translate each baffle element in order to selectively modify at least one of a shape or size of an aperture formed in the baffle array in real-time.

### CROSS-REFERENCE TO RELATED APPLICATIONS

This application claims the benefit of U.S. Provisional Application No. 62/204,377 filed on Aug. 12, 2015, which is hereby incorporated by reference in its entirety.

### STATEMENT OF GOVERNMENT INTEREST

The United States Government claims certain rights in this invention pursuant to Contract No. DE-AC02-06CH11357 between the U.S. Department of Energy and UChicago Argonne, LLC, as operator of Argonne National Laboratories.

### FIELD OF THE INVENTION

The present invention relates generally to the field of physical vapor deposition. More specifically, the present invention relates to a method and system for using a dynamic aperture system for three-dimensional control of thin-film deposition and ion-beam erosion.

### BACKGROUND

This section is intended to provide a background or context to the invention recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

Physical vapor deposition (PVD) processes, which are used throughout the globe for semiconductor fabrication, optics, photovoltaics (PV). etc. invariably suffer from thin-film non-uniformity because the deposition sources deplete during use and suffer from intrinsic manufacturing tolerances and defects themselves. These errors can lead to device failure in semiconductors, reduced efficiency or aberrations in optics, and solar light collection reduction in PVs.

Also, thin-film based optics such as x-ray multilayers can be produced with a maximum of one dynamically changing gradient and a second, fixed gradient along the complimentary lateral axis. This basic limitation means that optical systems that two-dimensionally focus either have aberrations or require two reflections. This results in added cost (two mirrors vs. one) or reduced optical efficiency.

Today, PVD deposition profiles are universally controlled or mitigated via the use of fixed apertures which consist of machined, metal plates that block portions of the PVD flux in a controlled manner. These fixed apertures must be physically replaced when a profile change is required.

In one application, an effective approach to the development of grazing-incidence X-ray telescopes for astronomy having a large collecting area and high resolution is the use of thin-shell cylindrical mirror segments that are nested as densely as possible. For example, each NuSTAR telescope contains 133 concentric mirror layers constructed from 0.21-mm-thick slumped glass segments. While there are many potential sources of figure error in thin-shell mirror substrate, the mid-spatial frequency (i.e., mm range) axial surface-height errors in particular have been identified as a limiting factor to achieving resolution below about 6 arc-seconds. Because these errors are generated by the slumping process itself, and not by the shell assembly/mounting processes, it is necessary to implement post-slumping surface correction in order improve the performance of X-ray telescopes constructed from these shells to 1 arc-second or better. To illustrate the problem, shown in FIG. 1 is a typical 1D axial surface profile of an approximately 6.5 arc-second HPD thin-glass shell. The measurement shows peak-to-valley residual surface height variations of order ˜60 nm, over spatial scales ranging from 1 to 20 mm. It is necessary to reduce these errors by a factor of approximately 5-10 in order to achieve sub-arc-second resolution.

In the conventional approach to differential deposition for surface error correction, a small, fixed-width aperture is placed in front of a source of deposited material, such as a planar magnetron cathode used for sputtering, where the width of the aperture determines the spatial distribution in one dimension of deposited atoms on the coated surface. As illustrated in FIG. 2(A), the substrate moves past the fixed aperture (or alternatively, the substrate and source are fixed and the aperture is moved). As seen in FIG. 2(B), differential deposition is used to correct surface-height errors by depositing more material in the “valleys,” and less material on the “hills.” In one mode, the substrate motion is continuous, and the substrate velocity, which is inversely proportional to the deposited film thickness, is modulated as the substrate moves past the aperture, in accord with the pre-measured surface-height profile. Alternatively, in a second mode (i.e., stepping mode) the substrate is moved from one position to the next, and the substrate dwell time at each position is adjusted in accord with the required film thickness to be deposited at that position.

The same techniques can be used for differential erosion, with the sputter source replaced by an ion source. As illustrated in FIG. 3(A), a fixed-width aperture is placed over an ion source, and the substrate moves past the aperture following a prescribed velocity profile that is determined by the pre-measured axial surface-height errors. In this case the amount of material removed from the glass surface due to ion erosion is inversely proportional to the substrate velocity, or in “stepping mode,” proportional to the substrate dwell time. As seen in FIG. 3(B), differential erosion is used to correct surface-height errors by eroding more material from the “hills,” and less material from the “valleys.”

As illustrated in FIG. 4(A), differential deposition and differential erosion techniques may be combined by placing a sputter source (e.g., a magnetron cathode) and an ion source side by side in the same chamber. By combining differential deposition and differential erosion techniques, it is possible to achieve a faster rate of surface correction, better surface finish, and/or reduced stress or thermal expansion mismatch induced distortions. As seen in FIG. 4(B), in one mode, differential deposition is used only to deposit material in the “valleys,” while differential erosion is used only to reduce the heights of the “hills.” As seen in FIG. 4(C), in another mode, the substrate surface is coated with a sacrificial layer of material of uniform thickness, and then differential erosion is used to correct the surface-height errors that are replicated in the deposited sacrificial layer. This latter approach might be preferable if the deposited film can be eroded more quickly than the underlying substrate material, for example, or if the surface finish of the eroded film is smoother than the surface finish of the eroded substrate.

In any case, the conventional approaches to differential deposition/erosion, as illustrated in FIGS. 2(A)-4(C), only works efficiently in one dimension, i.e., the direction of substrate motion, which is ostensibly parallel to the axial direction of a thin-shell glass substrate (e.g., a cylindrical mirror shell). If a fixed-width aperture that spans the full width of the substrate is used, then the same amount of material will be added or removed in the azimuthal direction, perpendicular to the direction of substrate motion, everywhere on the substrate. Assuming that surface-height errors also vary azimuthally, which is generally true in the case of thermally-formed, thin-shell glass substrates, the conventional approaches would thus only correct axial surface-height errors along one stripe on the cylindrical substrate. Surface-height errors would remain (or possibly worsen) everywhere else. If instead an approximately square-shaped aperture is used, then material is deposited or eroded only along one narrow stripe in the axial direction that is roughly as wide as the aperture. To correct axial surface-height errors over the entire substrate surface, the substrate would need to follow a raster scan, so as to correct surface errors over the whole surface one stripe at a time.

A need exists for improved technology, including technology that can modify PVD aperture profiles dynamically during the manufacturing process.

### SUMMARY

One embodiment of the invention relates to a dynamic aperture system including a plurality of dynamically-actuated baffle arrays, each dynamically-actuated array comprising multiple, identical actuated baffle elements, for real-time control of thin-film deposition and/or ion-beam erosion in three dimensions. The modular actuated baffle mechanism can be easily adapted to a variety of similarly-sized planar, rectangular magnetron cathodes, and rectangular ion sources, regardless of their specific dimensions. In some embodiments, the dynamic aperture system may be used with any of these sources without modification using replaceable dynamically-actuated baffle arrays that are specific to each type of source, and have dimensions that match that type of source. In other embodiments, a single dynamic aperture system may match multiple different types of sources and source dimensions.

Another embodiment of the invention relates to a dynamic aperture system that includes at least one baffle array comprised of a plurality of baffle elements, at least one source configured to provide atoms for differential deposition or ions for differential erosion, and an actuator configured to independently translate each baffle element in order to selectively modify at least one of a shape or size of an aperture formed in the baffle array in real-time.

Yet another embodiment of the invention elates to a method of correcting surface errors of a substrate. The method includes transporting a substrate past at least one source configured to provide atoms for differential deposition or ions for differential erosion, and translating at least one of a plurality of baffle elements disposed between the substrate and the source. Each baffle element in the plurality of baffle elements is independently translated in order to selectively modify at least one of a shape or size of an aperture formed in the plurality of baffle elements in real-time to control an amount of atoms or ions deposited on the substrate.

Additional features, advantages, and embodiments of the present disclosure may be set forth from consideration of the following detailed description, drawings, and claims. Moreover, it is to be understood that both the foregoing summary of the present disclosure and the following detailed description are exemplary and intended to provide further explanation without further limiting the scope of the present disclosure claimed.

### BRIEF DESCRIPTION OF THE DRAWINGS

The disclosure will become more fully understood from the following detailed description, taken in conjunction with the accompanying figures, in which:

FIG. 1 illustrates typical residual surface height errors in a slumped glass shell.

FIG. 2(A) illustrates a system for correcting surface height errors including a fixed-width aperture placed over a magnetron source.

FIG. 2(B) illustrates differential deposition used to correct surface height errors using the system of FIG. 2(A).

FIG. 3(A) illustrates a system for correcting surface height errors including a fixed-width aperture placed over an ion source.

FIG. 3(B) illustrates differential erosion used to correct surface height errors using the system of FIG. 3(A).

FIG. 4(A) illustrates a system for correcting surface height errors including a first fixed-width aperture placed over an ion source and a second fixed-width aperture placed over a magnetron source.

FIG. 4(B) illustrates the combined differential erosion and differential deposition used to correct surface height errors using the system of FIG. 4(A).

FIG. 4(C) illustrates a sacrificial layer of uniform thickness deposited on a substrate, and differential erosion used to correct the surface height errors of the sacrificial layer.

FIG. 5 illustrates a dynamic aperture system including actuated baffle elements, mounted on one side of a rectangular chimney that houses a cathode bank. The baffle elements are used to control deposition or erosion in real time. As a substrate travels linearly past a source, each baffle element moves such that a corresponding aperture opens or closes as necessary.

FIG. 6 illustrates an example of a baffle array of the dynamic aperture system of FIG. 5, where the baffle array includes five baffle elements.

FIG. 7 illustrates the dynamic aperture system of FIG. 5 disposed in a chamber. The dynamic aperture system also includes a linear motion mechanism configured to transport the substrate back and forth past a source.

FIG. 8 illustrates an example of a magnetron source including vertically-oriented cathodes.

FIG. 9 illustrates an example of a magnetron source including horizontally-oriented cathodes. FIG. 9 also includes a plurality of baffle arrays and apertures.

FIG. 10 illustrates an array of actuators configured to adjust each of the baffle elements of FIG. 5.

FIG. 11 illustrates an example of an actuation system used to adjust each of the baffle elements of FIG. 5.

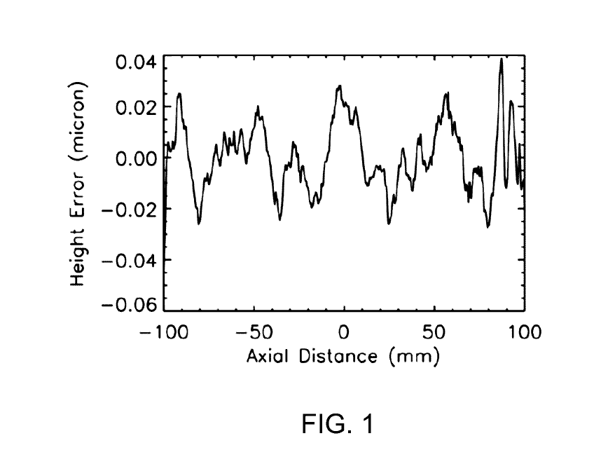

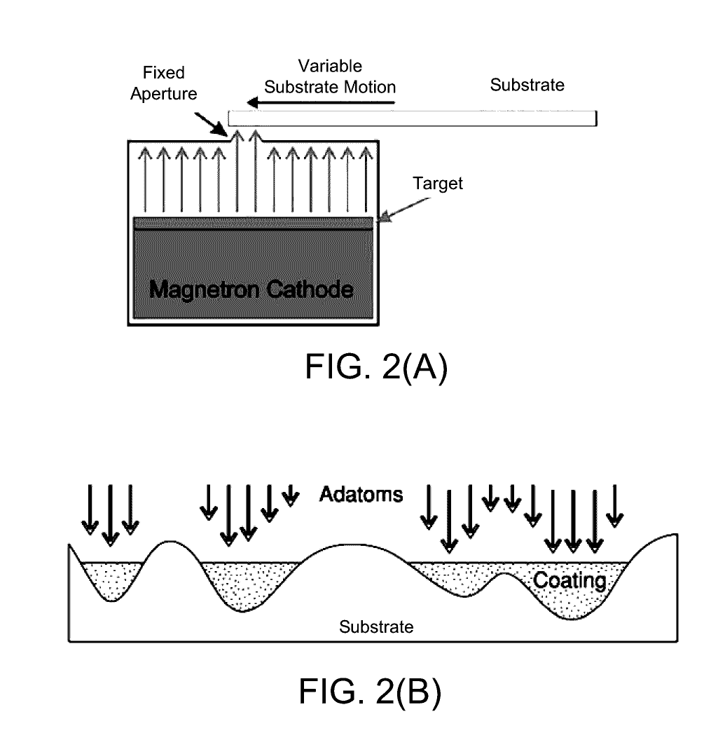

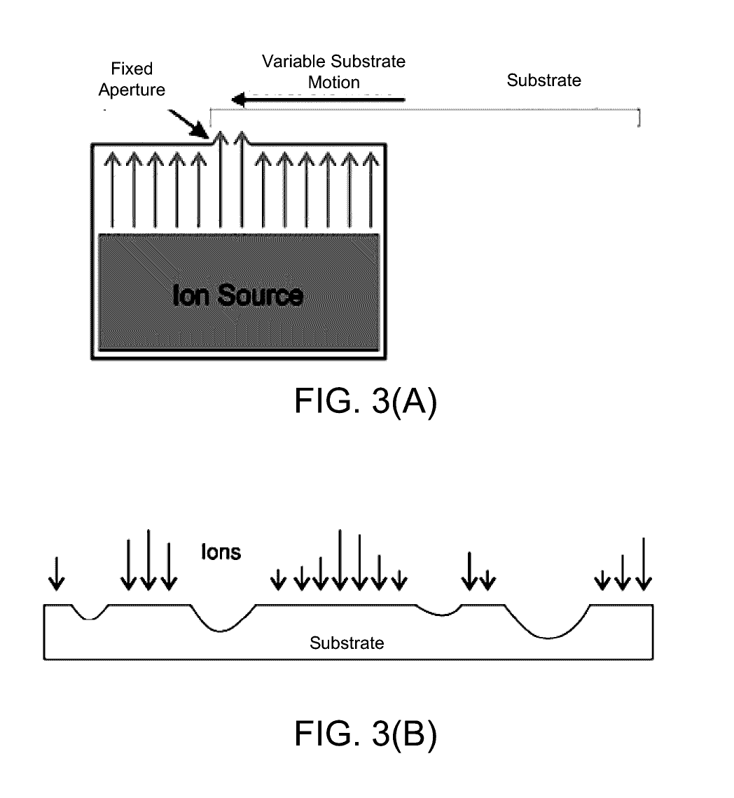

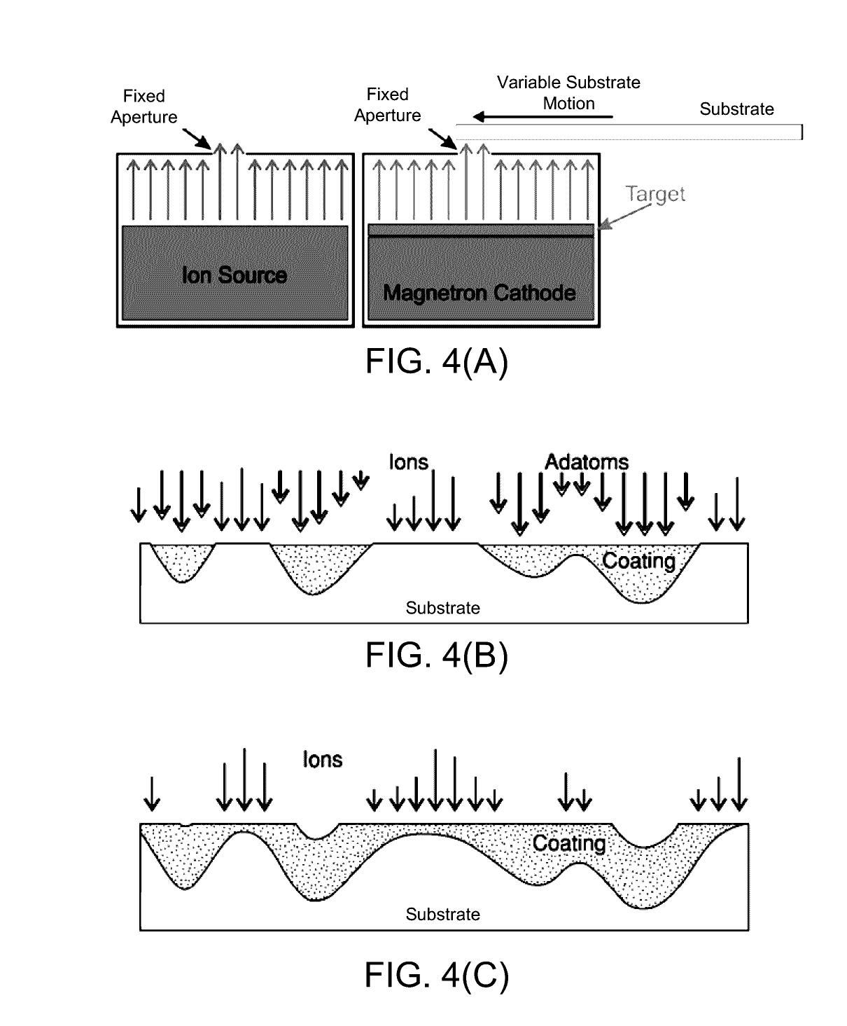

### DETAILED DESCRIPTION

Before turning to the figures, which illustrate the exemplary embodiments in detail, it should be understood that the present application is not limited to the details or methodology set forth in the description or illustrated in the figures. It should also be understood that the terminology is for the purpose of description only and should not be regarded as limiting.

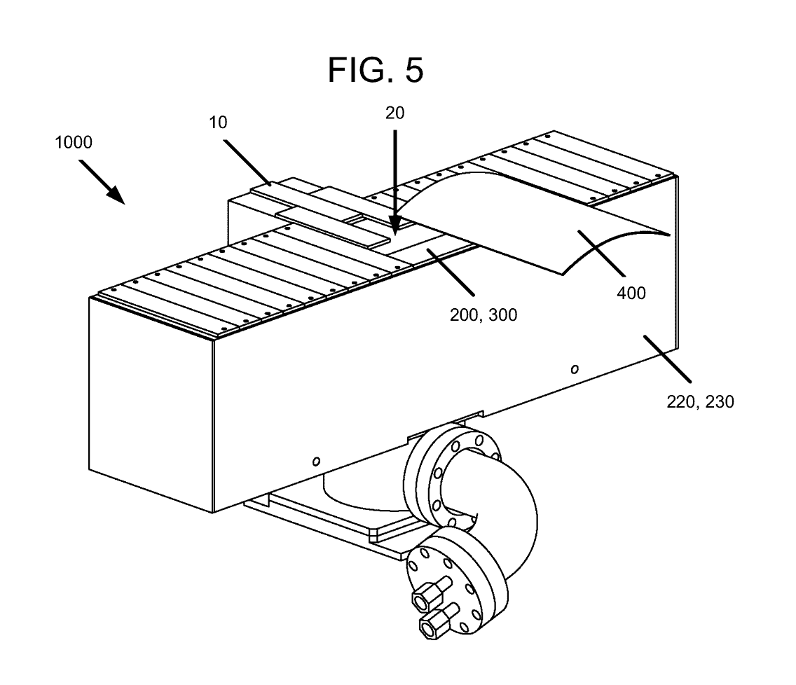

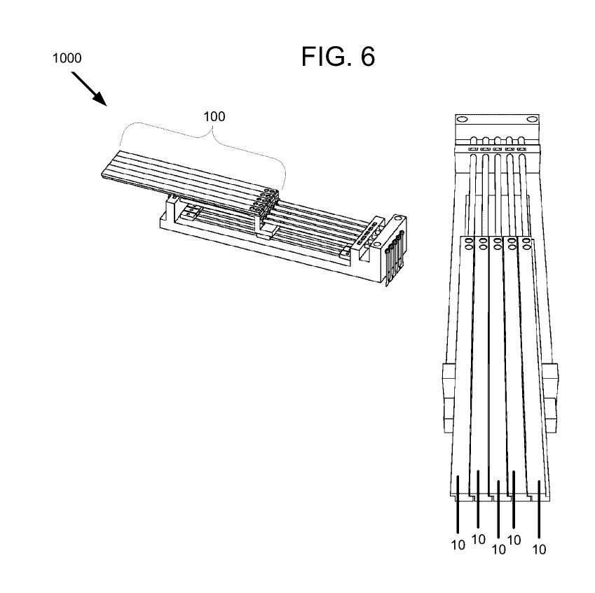

Referring, in general, to the figures, a dynamic aperture system (described in the embodiments below) allows for two-dimensional or three-dimensional control of thin-film deposition and ion-beam erosion. As illustrated in FIGS. 5-7 and 9, a dynamic aperture system 1000 includes at least one baffle array 100 comprised of a plurality of fingers or baffle elements 10. The baffle elements 10 may be vacuum-compatible and plasma tolerant. In the example of FIG. 6, a single baffle array 100 includes five baffle elements 10, but any number of baffle elements 10 may be used.

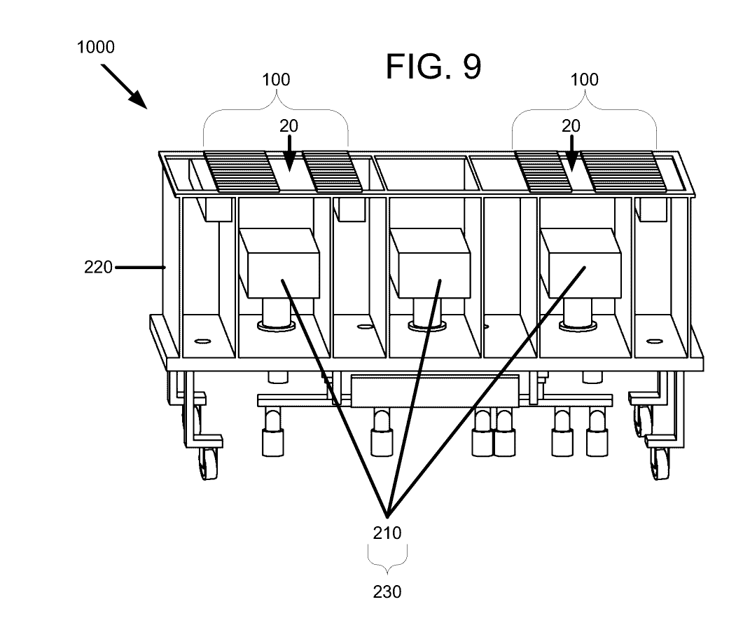

The dynamic aperture system 1000 may include a plurality of baffle arrays 100 (see FIG. 9). In one aspect, the dynamic aperture system 1000 further includes at least one PVD source 200 configured to provide vaporized material for differential deposition (i.e., physical vapor deposition). In another aspect, instead of the PVD source 200, the dynamic aperture system 1000 includes at least one ion source 300 configured to provide ions for differential erosion (i.e., ion erosion). In yet another aspect, the dynamic aperture system 1000 includes at least one PVD source 200 and at least one ion source 300 such that the dynamic aperture system is capable of performing both differential deposition and differential erosion. In all aspects, the dynamic aperture system 1000 further includes a linear motion mechanism 500 configured to transport a substrate 400 back and forth past the PVD source 200 and/or the ion source 300.

When the dynamic aperture system 1000 is used for differential deposition, any physical vapor deposition process (e.g., cathodic arc deposition, electron beam physical vapor deposition, evaporative deposition, pulsed laser deposition, or sputter deposition) may be utilized. In the examples discussed below, sputtering is selected as the physical vapor deposition process, and therefore, the source 200 is a magnetron source. However, the application is not limited in this regard. The source 200 is selected based on the physical vapor deposition process selected, and therefore, may be any other suitable source such as a cathodic arc or electron beam source.

When the dynamic aperture system 1000 is used for differential erosion, the source 300 may be any suitable ion source (e.g., an Ar⁺ ion source).

A position of each baffle element 10 in the baffle array 100 is configured to be adjusted independently of a position of another baffle element 10 in the baffle array 100. By adjusting a position of each baffle element 10, a size (area), shape or position of an aperture 20 may be dynamically changed. For example, the baffle elements 10 may be translated such that the shape and size of the aperture 20 is widened to deposit more material on the substrate 400 and to translate such that the shape and size of the aperture 20 is narrowed to deposit less material on the substrate 400. When the dynamic aperture system 1000 includes a plurality of baffle arrays 100, the baffle elements 10 of each baffle array 100 are adjusted independently of the baffle elements 10 of the other baffle arrays 100. As a result, a plurality of apertures 20 having different sizes and positions may be simultaneously used in the deposition and erosion surface error correction processes of the dynamic aperture system 1000. In the example of FIG. 5, the left-most baffle element 10 is fully extended (75 mm), the middle baffle element 10 is fully retracted (0 mm), and the right-most baffle 10 is positioned mid-way. The baffle elements 10 shown here are not to scale, and are for illustration only.

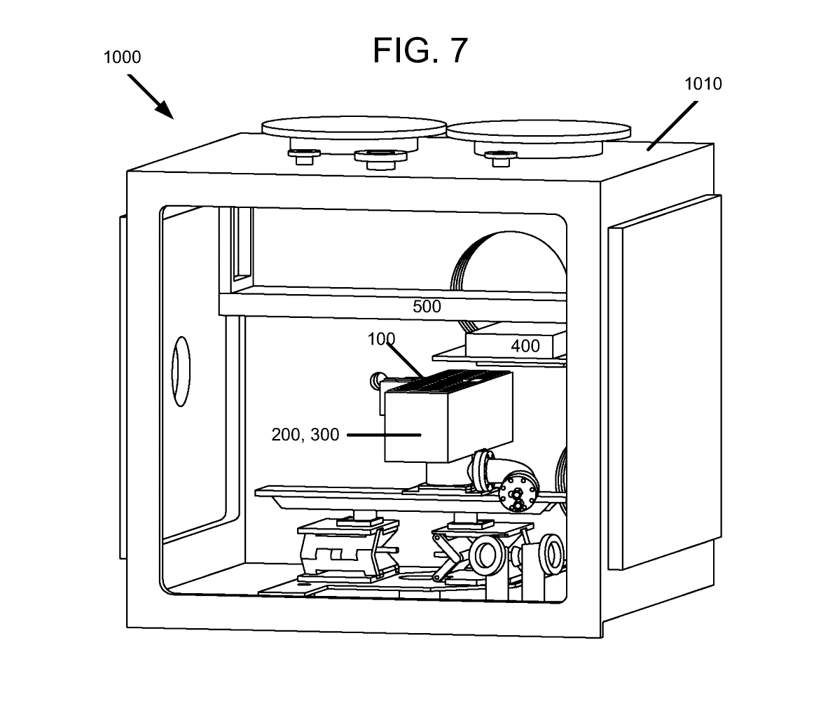

In one embodiment, the position of each baffle element 10 may be adjustable only prior to deposition or erosion, when the baffle elements 10 can be accessed at a time in which a chamber 1010, which houses the dynamic aperture system 1000 (see FIG. 7), is at atmospheric pressure. This embodiment may be used, for example, to deposit steep, laterally-graded multilayer coatings such as those used for soft X-ray polarimetry applications, following an iterative procedure in which the positions of the baffle elements 10 are individually fine-tuned, based on the uniformity achieved in previous coating runs, until acceptable coating uniformity is achieved.

In another embodiment, the position of each baffle element 10 may be adjusted during deposition or erosion. Thus, it is preferable to include a minimum number of moving parts, all of which must be sufficiently shielded from vaporized material and/or ions. In this embodiment, the baffle elements 10 can independently translate in order to selectively restrict or modify the aperture shape in real-time.

The baffle elements 10 may be manually or electronically actuated. The actuated baffle elements 10 are configured to control the amount of material deposited or eroded along parallel lines (whose widths are determined by the baffle width and pitch) along a surface of a substrate 400, as the substrate 400 travels back and forth past the PVD source 200 and/or the ion source 300 at constant speed along the short axis of the PVD source 200 and/or the ion source 300. That is, the actuated baffle elements 10 are configured to translate such that the aperture 20 opens wider to deposit or erode more material, and are further configured to translate such that the aperture 20 is closed or narrowed to deposit or erode less material.

In embodiments in which the baffle elements 10 are electronically actuated, a computer-controlled motion of each individual baffle element 10 may be pre-determined, based on the desired film or erosion profile. In other words, a control unit or processor may be programmed to move each of the individual baffles 10 to a desired position at a desired time, based on the desired film or erosion profile.

The baffle arrays 100 may be retrofit to an existing physical vapor deposition apparatus including the PVD source 200, an existing ion erosion apparatus including the ion source 300, or an existing apparatus including both the PVD source 200 and the ion source 300. As illustrated in the figures, the PVD source 200 and the ion source 300 are rectangular and planar. However, the PVD source 200 and the ion source 300 can be any shape, provided the source is configured to provide a directional flow of atoms, adatoms, or ions for deposition or erosion.

In the examples described below, the dynamic aperture system 1000 includes a magnetron source 200. However, as discussed above, any other type of PVD source 200 may be used. In addition, the ion source 300 may be used instead of or in addition to the magnetron source 200.

In one example, the PVD source 200 is a magnetron source that includes at least one magnetron cathode 210. In one aspect (see FIG. 9), the magnetron source 200 is comprised of a cathode bank 230, which includes a plurality horizontally-oriented magnetron cathodes 210 that are, for example, approximately 50 cm long×14 cm wide. As shown in FIG. 9, in this example, the substrate 400 is oriented horizontally and faces down towards the magnetron cathodes 210.

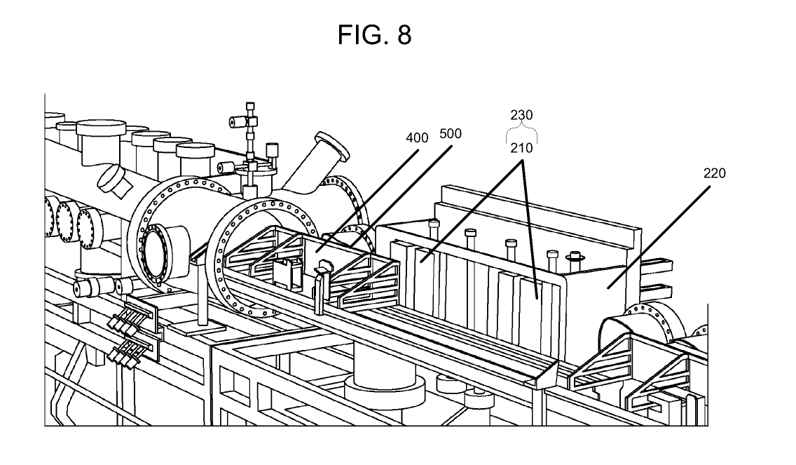

In another aspect (see FIG. 8), the magnetron source 200 is comprised of a cathode bank 230, which includes a plurality of vertically-oriented magnetron cathodes 210 that are, for example, approximately 30 cm long (high)×15 cm wide.

In both embodiments (FIGS. 8 and 9), the cathode bank 230 is contained in a housing or chimney 220 configured to shield material (e.g., atoms, adatoms or ions) from traveling to undesired locations. Although the chimney 220 is illustrated as a rectangular chimney 220, the chimney 220 can be any shape. The baffle elements 10 are mounted to one side of the chimney 220 (e.g., a side, open portion of the chimney 220 in FIG. 8 or a top, open portion of the chimney 220 in FIG. 9), for example, using mounting holes. In addition, in both embodiments, the lengths of the baffle elements 10 are matched to the lengths of the magnetron cathodes 210 such that a travel range of the baffle element 10 spans all or most of the width of the magnetron cathode 210. As shown in FIG. 8, the substrate 400 is oriented vertically in a linear motion mechanism 500 (e.g., a carriage), and faces the magnetron cathodes 210. The cathode bank 230 includes side plates to which the baffle elements 10 are mounted.

In any of the embodiments of the dynamic aperture system described above, a surface of the substrate 400 may be coated with a sacrificial layer of material of uniform thickness, and then differential erosion may be used to correct the surface-height errors that are replicated in the deposited sacrificial layer.

The dynamic aperture system takes into account the following considerations:

### Environmental

The base pressure of the dynamic aperture system 1000 described in the first and second example above is approximately 10⁻⁸ torr. The baffle elements 10 must work reliably at this pressure. The baffle elements 10 are constructed from ultra-high vacuum (UHV) compatible materials. Any outgassing from the baffle elements 10 should have no measureable effect on the base pressure of the chamber 1010 housing the dynamic aperture system 1000, or any measureable effect on the composition of the residual gases present in the chamber 1010, as determined by a residual gas analyzer (RGA).

The baffle elements 10 must work in the harsh vacuum environment of PVD and erosion systems (e.g., magnetron sputtering or ion beam erosion systems). All exposed surfaces (not just those directly facing the target surface of the PVD source 200 and/or the ion source 300) will be subject to coating from the PVD source 200 and/or the ion source 300. All sensitive components and mechanisms, therefore, must be protected from coating using robust shielding that can be easily removed for periodic cleaning or replacement as necessary.

The baffle elements 10 are configured to be easily removed for cleaning or replacement. For example, the baffle elements 10 may be individually removed for cleaning or replacement.

Maximum temperature is expected to be less than 80 C.

### Motion Control

The range of motion of the baffle elements 10 may be between 0-300 mm (e.g., for large magnetron cathodes 210 having a diameter of 300 mm or larger). In some embodiments, the range of motion of the baffle elements 10 may be between 50-250 mm, for example, 75 mm. In other embodiments, the range of motion of the baffle elements 10 may be between 100-200 mm, between 110-190 mm, between 120-180 mm, between 130-170 mm, or between 140-160 mm. The range of motion of the baffle elements 10 is preferably greater than 20 mm. All of these ranges assume the same origin point frame of reference.

The speed of actuation of the baffle elements 10 is preferably, “as fast as possible,” but no less than 20 mm/sec.

An Absolute Position Encoders or a homing switch (not illustrated) is provided for each baffle element 10. Position resolution is preferably 50 microns or better. If a multiplexing scheme is to be used to control multiple actuators with a single controller, changes in position must be able to occur at a rate of 10 Hz or higher. However, in other applications of the dynamic aperture system, for example, if the dynamic aperture system is used to compensate for very slow changes in the deposition/ion beam profile due to source changes such as source depletion, the feedback refresh rate may be much slower than 10 Hz. For example, a deposition run may take a day or even a week, and the refresh rate may be once per deposition run.

### Mounting and Dimensions

The baffle elements 10 are located on one side of the PVD source 200 or the ion source 300 (e.g., on one side of the magnetron cathodes 210, as seen in the examples of FIGS. 5 and 7-10). Nothing should extend significantly above the plane of the baffle elements 10, as the substrate 400 will be located as close to this plane as possible, as the substrate 400 travels past the PVD source 200 or the ion source 300 during deposition or erosion, respectively. Also, the extent of the baffle elements 10 that are perpendicular to the side of the chimney 220 should be made as small as possible, so that two or more magnetron cathodes or ion guns can be placed as close together as possible.

The nominal width of each baffle element 10 may be, for example, approximately 5 mm, 6 mm, 10 mm, 15 mm or 20 mm. Adjacent baffle elements 10 may be spaced on a pitch identical to the width of the baffle elements 10. For example, the pitch may be approximately 5 mm, 6 mm, 10 mm, 15 mm or 20 mm. The width of the baffle elements 10 in the direction perpendicular to the direction of substrate motion (e.g., the azimuthal direction with respect to a cylindrical substrate) must be small enough to allow for axial surface error corrections to be made along adjacent stripes on the substrate surface with sufficient azimuthal resolution, as determined by the actual azimuthal variation in axial figure errors on the substrate. It is preferable for the width and pitch of the baffle elements 10 to be the same or very close, but in examples in which the width and pitch of the baffle elements 10 are not the same, a small shield may be provided between each baffle element 10.

### Wiring and Utility Access

Given that a large number of dynamic apertures 20 will be used simultaneous to correct surface errors, the actuation mechanisms must be highly reliable, and the number of wires needed to control each dynamic aperture 20 (i.e., to control the actuation of the baffle elements 10 that determine the size and position of the dynamic aperture 20) must be minimized so that the electrical vacuum feed-through requirements are manageable.

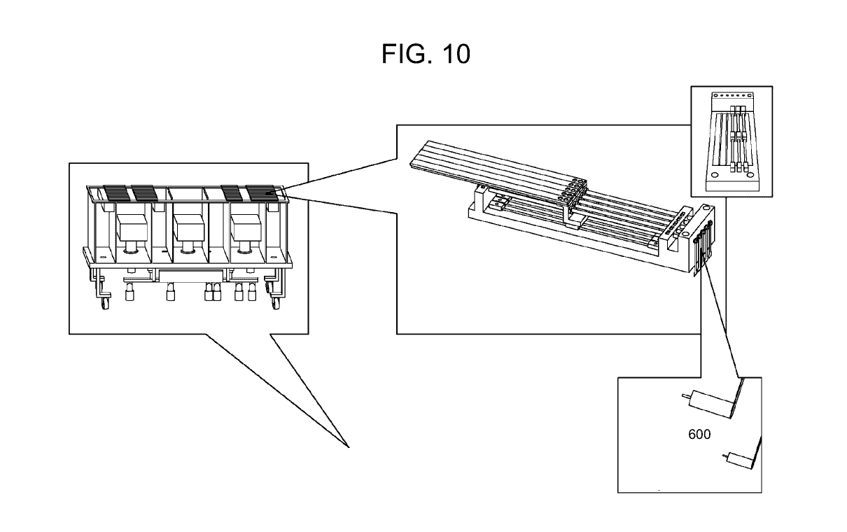

The dynamic aperture system 1000 includes an array of actuators 600 (see FIG. 10), for example, custom-specified micro UHV compatible stepper motors or brushless DC motors coupled with an encoder system, and linear guides that allows an arbitrary mask shape to be produced in vacuum, during coating or ion milling applications. Alternatively, the baffle elements 10 may be actuated by a BLDC motor, piezo-based actuators, UHV voice coils, linear motors, or stepper motors for motive force.

In one embodiment, the baffle elements 10 are actuated using a plurality of stepper motors and a single limit switch. According to this configuration, it is possible to home the position of the baffle element 10 against the limit switch, and then make step moves such that an encoder is not required. The number of stepper motors corresponds to the number of baffle elements 10 (e.g., one stepper motor per each baffle element 10).

In another embodiment, each baffle element 10 includes one motor (e.g., a brushless DC motor) and one encoder. The encoder may be, for example, a store-bought UHV encoder (such as an optical encoder by Renishaw called the ATOM or Resolute) or a custom-designed encoder using a thick-film technology where a resistive strip is screen-printed and position is read by measuring resistance at the location of the mechanism.

In one example, the PVD source 200 is a magnetron source that has an available 8″ CF port located in the center of the bottom of the its housing that can be used for electrical feedthroughs. In an example in which the PVD source 200 is a magnetron source, depending on where each cathode 210 is mounted, the distance to this port is approximately 50 cm or less. The advanced photon source deposition system (APS) is a stand-alone deposition system that is expected to have a 100 mm×300 mm wire-seal flange for each cathode 210, located 200 mm away, which can be populated with several electrical feedthroughs as required. For both the horizontally and vertically-oriented magnetron cathodes 210, a plurality of multi-pin high density UHV connectors are required, for example dual DB25 or DB50. However, such connectors are not optimized for high-speed signal isolation. If high-speed signaling is required, RF feedthroughs may be necessary.

The control electronics may be located, for example, approximately three meters from the electrical vacuum feedthroughs on the atmosphere side of the chamber 1010, for both the horizontally and vertically-oriented magnetron cathodes 210 of the magnetron source 200.

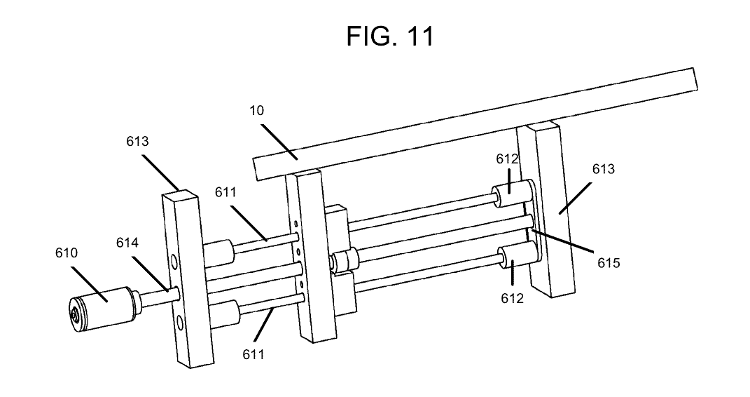

In the example of FIG. 11, the actuator 600 of a baffle element 10 is illustrated. The actuator 600 includes a motor 610 (e.g., a stepper motor), and two cylindrical, linear rods 611 having a linear rod end housing 612 to provide positional constraint. The rods 611 may be, for example, stainless steel or titanium rods. The rods 611 are press-fit into sleeves, which are coupled to at least one end block 613, for example, via screws. An acme-threaded leadscrew 614 is captured with a bearing clamp 615 in one end block 613 for compliancy. The embodiment of FIG. 11 optionally includes an encoder, but an encoder is not necessary. The encoder may utilize thick-film screen printing technology. In particular, a resistive ink may be screen printed onto an alumina substrate, and a small contactor may be provided to short the resistor to ground. The resistance measured on the fixed end of the encoder provides the position of the baffle element.

The dynamic aperture system (described in the embodiments above) allows for three-dimension control of thin-film deposition and ion-beam erosion without the need to stop the manufacturing process, saving time, money, and energy. The dynamic aperture system can also be used to improve a surface figure in mirrors and optics, as well as in previously fabricated thin-film based devices. Additionally, the dynamic aperture system allows for creation of truly 3D deposition or erosion profiles in materials and coatings.

Three non-limiting examples of applications using the dynamic aperture system including actuated baffle elements include: (1) deposition of X-ray multilayer films having arbitrary lateral thickness gradients in one dimension onto flat or figured substrates; (2) deposition of X-ray multilayer films having arbitrary lateral thickness gradients in two dimensions onto flat or figured substrates; and (3) differential deposition and/or differential erosion (i.e., ion-beam figuring) to correct surface figure errors in flat or figured substrates, including cylindrical thin-shell glass X-ray mirror substrates. Each of these three applications utilizes actuated baffle arrays, albeit in slightly different ways or orientations. For example, in the first application, the individual baffle elements that comprise the baffle array may be positioned at specific pre-determined locations and remain static during the course of the multilayer film deposition. In examples of the second and third applications, however, the baffle element positions may be adjusted in real time during deposition. The speed of the baffle elements in the first application may be the same or different than the speed of the baffle elements in the third application. In any case, the third application—differential deposition (erosion)—is the most general, and results in the most challenging baffle array motion requirements. However, it should be appreciated that the dynamic aperture system can be utilized with other systems or subtractive processes.

The dynamic aperture system may also be used in the high-end semiconductor fabrication industry. For example, high-end test and measurement equipment ICs require precisely tailored film thickness uniformity over the entire wafer and this is currently tuned by hand by filing masks. The dynamic aperture system would vastly shorten the time required for calibration of these deposition machines.

The dynamic aperture system described in the embodiments above offers, for the first time, a method to produce truly three-dimensional thickness gradients within a film or coating. This can be used for generation of (for example, but not limited to) single-reflection mirrors that beam shape in both dimensions such as an elliptical toroid mirror, for real-time deposition uniformity correction, and massively parallel form error correction via either deposition or ion milling on optics such as (for example) thin-shell slumped glass.

The dynamic aperture system can also be used in the solar industry. In particular, the dynamic aperture system can be used to increase PV efficiency with more precise layer deposition, reduce equipment downtime, lower raw material cost and impact multiple steps of PV manufacturing processes. See Appendix for more information on solar applications.

The construction and arrangements of the dynamic aperture, as shown in the various exemplary embodiments, are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, image processing and segmentation algorithms, etc.) without materially departing from the novel teachings and advantages of the subject matter described herein. Some elements shown as integrally formed may be constructed of multiple parts or elements, the position of elements may be reversed or otherwise varied, and the nature or number of discrete elements or positions may be altered or varied. The order or sequence of any process, logical algorithm, or method steps may be varied or re-sequenced according to alternative embodiments. Other substitutions, modifications, changes and omissions may also be made in the design, operating conditions and arrangement of the various exemplary embodiments without departing from the scope of the present invention.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

References herein to the positions of elements (e.g., “top,” “bottom,” “above,” “below,” etc.) are merely used to describe the orientation of various elements in the FIGURES. It should be noted that the orientation of various elements may differ according to other exemplary embodiments, and that such variations are intended to be encompassed by the present disclosure.

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

Embodiments of the subject matter and the operations described in this specification can be implemented in digital electronic circuitry, or in computer software embodied on a tangible medium, firmware, or hardware, including the structures disclosed in this specification and their structural equivalents, or in combinations of one or more of them. Embodiments of the subject matter described in this specification can be implemented as one or more computer programs, i.e., one or more modules of computer program instructions, encoded on one or more computer storage medium for execution by, or to control the operation of, data processing apparatus. Alternatively or in addition, the program instructions can be encoded on an artificially-generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate components or media (e.g., multiple CDs, disks, or other storage devices). Accordingly, the computer storage medium may be tangible and non-transitory.

The operations described in this specification can be implemented as operations performed by a data processing apparatus or processing circuit on data stored on one or more computer-readable storage devices or received from other sources.

The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors or processing circuits executing one or more computer programs to perform actions by operating on input data and generating output. The processes and logic flows can also be performed by, and apparatus can also be implemented as, special purpose logic circuitry, e.g., an FPGA or an ASIC.

Processors or processing circuits suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing actions in accordance with instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display), OLED (organic light emitting diode), TFT (thin-film transistor), plasma, other flexible configuration, or any other monitor for displaying information to the user and a keyboard, a pointing device, e.g., a mouse trackball, etc., or a touch screen, touch pad, etc., by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

What is claimed:

1. A dynamic aperture system comprising:
at least one baffle array comprised of a plurality of baffle elements;
at least one source configured to provide atoms for differential deposition or ions for differential erosion; and
an actuator configured to independently translate each of the plurality of baffle elements in order to selectively modify at least one of a shape or size of an aperture formed in the baffle array in real-time.

2. The dynamic aperture system of claim 1, wherein each baffle element is configured to translate such that the size of the aperture is increased to deposit more atoms or ions on a substrate and to translate such that the size of the aperture is decreased to deposit less atoms or ions on the substrate.

3. The dynamic aperture system of claim 1, wherein the actuator comprises at least one brushless DC motor and an encoder.

4. The dynamic aperture system of claim 1, wherein the actuator comprises a plurality of stepper motors and a single limit switch.

5. The dynamic aperture system of claim 1, wherein the at least one baffle array comprises a plurality of baffle arrays, wherein the plurality of baffle elements of each of the plurality of baffle arrays are configured to translate independent of the baffle elements of another baffle array.

6. The dynamic aperture system of claim 5, further comprising a plurality of apertures, each aperture of the plurality of apertures having an associated shape and size.

7. The dynamic aperture system of claim 6, wherein the plurality of apertures each have the same shape and size.

8. The dynamic aperture system of claim 6, wherein at least one aperture has a different shape, size, or a combination thereof than another aperture.

9. The dynamic aperture system of claim 1, wherein the source is a physical vapor deposition source configured to provide atoms for differential deposition.

10. The dynamic aperture system of claim 1, wherein the source is an ion source configured to provide ions for differential erosion.

11. The dynamic aperture system of claim 1, wherein the dynamic aperture system includes a first source configured to provide atoms for differential deposition and a second source configured to provide ions for differential erosion.

12. The dynamic aperture system of claim 1, wherein the source is a magnetron source configured for differential deposition by sputtering, the magnetron source comprising a plurality of magnetron cathodes.

13. The dynamic aperture system of claim 1, further comprising a linear motion mechanism configured to transport a substrate back and forth past the at least one source.

14. A method of correcting surface errors of a substrate, the method comprising:
transporting a substrate past at least one source configured to provide atoms for differential deposition or ions for differential erosion; and
translating at least one of a plurality of baffle elements disposed between the substrate and the source,
wherein each baffle element of the plurality of baffle elements is independently translated in order to selectively modify at least one of a shape or size of an aperture formed in the plurality of baffle elements in real-time to control an amount of atoms or ions deposited on the substrate.

15. The method of claim 14, wherein each baffle element is configured to translate such that the size of the aperture is increased to deposit more atoms or ions on the substrate and to translate such that the size of the aperture is decreased to deposit less atoms or ions on the substrate.

16. The method of claim 14, wherein the plurality of baffle elements are translated using at least one brushless DC motor and an encoder.

17. The method of claim 14, wherein the plurality of baffle elements are translated using a plurality of stepper motors and a single limit switch.

18. The method of claim 14, wherein the source is a physical vapor deposition source, and the substrate is transported past the physical vapor deposition source to correct surface errors of the substrate via differential deposition.

19. The method of claim 14, wherein the source is an ion source, and the substrate is transported past the ion source to correct surface errors of the substrate via differential erosion.

20. The method of claim 14, further comprising:
depositing a sacrificial layer of material on the substrate, and subsequently transporting the substrate past the source to correct surface errors that are replicated in the sacrificial layer via differential erosion,
wherein the source is an ion source.
